(19) United States
(12) Patent Application Publication
(10) Pub. No.: US 2012/0223849 A1
(43) Pub. Date: Sep. 6, 2012

(54) SET-POINT RESOLUTION IMPROVEMENT FOR SWITCH MODE POWER SUPPLIES

(75) Inventors: Lawrence BROWN, WAKE FOREST, NC (US); JASON WEINSTEIN, TORONTO (CA); ZHENYU ZHAO, BURLINGTON (CA); ZONGGI HU, FREMONT, CA (US)

(73) Assignee: EXAR CORPORATION, FREMONT, CA (US)

(21) Appl. No.: 13/039,552

(22) Filed: Mar. 3, 2011

(51) Int. Cl. H03M 1/20

(52) U.S. Cl. 341/131

(57) ABSTRACT

A Digital-to-Analog Converter (DAC) produces an analog reference value from a first reference input. The analog reference value and an output value are used to produce an analog error signal. An Analog-to-Digital Converter (ADC) converts the analog error signal to a digital value. The ADC has higher level of resolution than the DAC. An error encoder adjusts the digital value to produce a digital error value using a second reference input.

### BACKGROUND

As power management tasks become more and more sophisticated in power electronics applications, the advantage of a programmable output voltage has been recognized by the industry. For example, in some applications, the output voltage is intentionally set a few percent lower than its nominal level to save power consumed by the load. This is also the case for dynamic voltage scaling applications where the output voltage transitions from one level to another depending on load conditions. Furthermore, to achieve a soft-start of the converter operation, the reference voltage usually follows a linear ramp, which starts from zero volts and ends at steady state set-point voltage.

Traditionally, the reference voltage is generated by a Digital-to-Analog Converter (DAC), which determines the programmability and resolution of the set-point. To ensure both a smooth soft-start ramp and an accurate output voltage with fine set-point resolution in steady state, the reference DAC requires a very fine step, sometimes in sub mV range, and a large dynamic range. However, such a DAC design usually takes large silicon area due to the large number of bits. For example, to achieve 2.5 mV DAC resolution in 0-3.2V range, an 11-bit DAC is required. For each additional bit of resolution, the size of the DAC increases exponentially by a factor of two.

### SUMMARY

Embodiments of the present invention use two reference inputs. The first reference input is sent to the DAC as normal. The second reference input is used to shift the output of an ADC that digitizes an analog error signal. The ADC typically has a higher resolution that the DAC since the ADC is windowed to digitalize the analog error signal which has a narrower range than the output value being controlled. The shift produced by the second reference input produces an improved set point resolution.

### BRIEF DESCRIPTION OF THE DRAWINGS

FIG. 1 is a diagram of an embodiment of the present invention that shifts the output of an ADC to get better reference (set point) resolution.

FIG. 2 is a diagram of an embodiment of the present invention for use with a DC-to DC converter

FIG. 3 is a diagram that illustrates the operation of the use of a shift of the reference (set point) value.

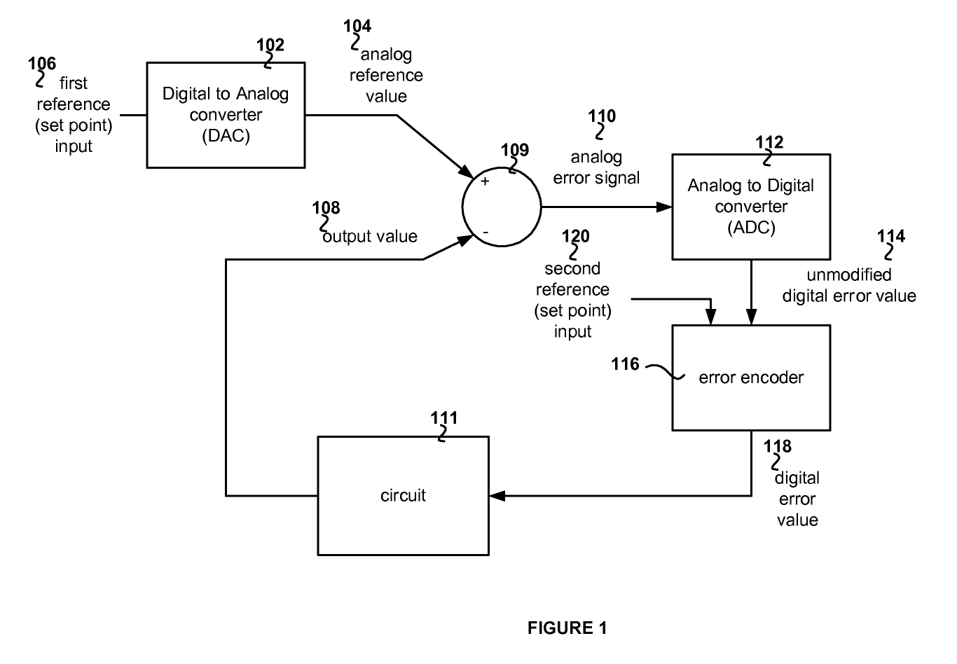

### DETAILED DESCRIPTION

A Digital-to-Analog Converter (DAC) 102 produces an analog reference value 104 from a first reference (set point) input 106. The analog reference value 104 and an output value 108 are used to produce an analog error signal 110.

The output value 108 is an output of circuit 111, such as a dc-to-dc converter. The output value 108 can be a voltage or current value.

The output value 108 is subtracted from the analog reference value 104 using subtracter 109 to produce the analog error signal 110.

An analog-to-digital converter (ADC) 112 converts the analog error signal 110 to a digital value (unmodified digital error value) 114. The ADC 112 has a higher level of resolution than the DAC 102.

An error encoder 116 adjusts the digital value 114 to produce a digital error value 118 using a second reference (set point) input 120. The error encoder 116 can add the second reference (set point) input 120 to the digital error value 118. The second digital reference input shifts the digital error signal to effectively fine adjust the reference voltage (set point).

The ADC 112 can be a windowed ADC 112 that operates over a narrower range than the DAC 102. In one embodiment, the ADC 112 can encode steps that are an integer n times smaller than the steps produced by the DAC 102.

The digital error value 118 is used to adjust the output value 108 of the circuit 111.

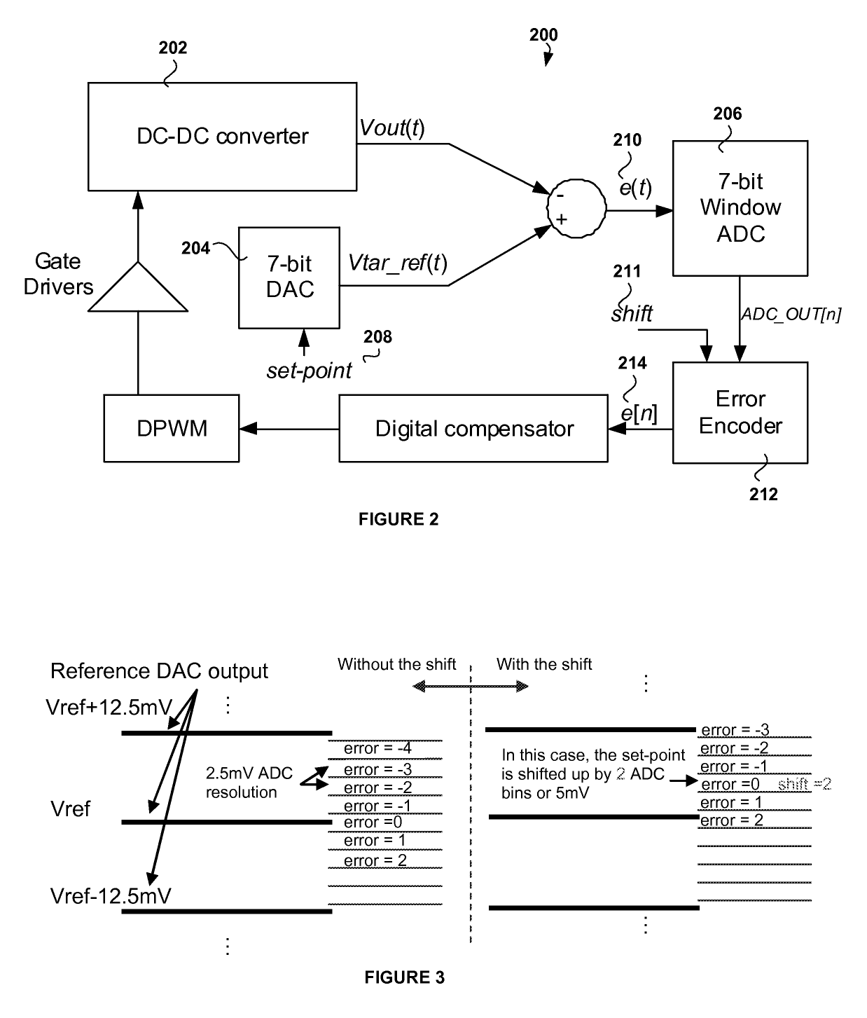

FIG. 2 shows an example for a DC-to-DC converter 202 that produces an output voltage which is controlled by the error signal using the system of the present invention.

Fine set-point resolution can also be achieved with a full-range voltage feedback ADC of a digital controller, which converts output voltage to digital domain. The output regulation error signal is produced by taking the difference between the ADC output and a digital set point value. The output voltage at the set-point level will result in zero regulation error in steady state and the ADC bin corresponds to zero error is called zero-error bin. If the ADC has a dynamic range covering the full range of converter operation, e.g. from zero volt to converter's maximum output voltage, the set-point can be set freely at any point in this range. Therefore, the digital set-point resolution is the same as the ADC resolution/quantization step. However, an ADC that has such a large dynamic range and as well a very fine resolution again requires large die size and high power and is not practical in controllers for low power converters.

In this embodiment, a modest resolution DAC 204 and a high resolution windowed ADC 206 with a narrow dynamic range are combined to achieve high set-point voltage resolution. The input range of the ADC 206 is centered at the reference DAC 204 output where zero-error bin is located. The idea is to combine the input code of the reference DAC 204 and the encoded ADC 206 output for improving the set-point voltage resolution. The set-point value 208 in a coarse resolution is first sent to the reference DAC 204. The fine steps, however, is achieved by employing different error encoding schemes of the ADC 206 to shift zero-error bin up or down by the fine resolution part 211 of the set-point value. In this way, we can achieve resolution the step size of the ADC quantization while the set-point range can still be extended to the full range of converter operation by utilizing a modest DAC design.

A block diagram 200 of the closed-loop system for an exemplary application is shown in FIG. 2. First, a reference DAC 204 with 7 bit resolution is constructed to generate an output voltage in the range of 0V-to-1.6V. The quantization step of the DAC 204 is therefore 1.6/128=12.5 mV. The purpose of this DAC 204 is to generate a coarse-step reference voltage for the ADC 206 according to the set-point input. Then, a 7-bit windowed ADC 206 with fine resolution of 2.5 mV is constructed to convert the analog regulation error 210, e(t), which is the difference between the reference voltage from DAC 204 and the feedback voltage from converter's output, to digital domain. It is then followed by an error encoder 212 to produce the error signal in digital domain 214, e[n]. The total dynamic range of the windowed ADC is 320 mV, which is much less than output range of 1.6V.

Initially, this conversion process is represented by the following equation:

e[n]=e(t)/Vq=(Vtar_ref−V_out)/Vq (1)

where Vq is the quantization step i.e. 2.5 mV. Thus, zero error value is produced when Vout is equal to Vtar_ref.

To improve the set-point resolution, a digital offset 211, shift, is introduced to the error encoder following the ADC output. In the end the digital error is represented by:

e[n]=(Vtar_ref−Vₒᵤₜ)/Vq+shift (2)

The above equation can be rearranged as:

e[n]=((Vtar_ref+shift*Vq)−V_out)/Vq (3)

As we can see, equation (3) is equivalent to a special case of (1) where the reference voltage changes to ((Vtar_ref+shift*Vq). Thus, the resolution has increased from the DAC 204 resolution of 12. mV to the ADC 206 resolution, i.e. Vq of 2.5 mV. The added offset can be programmed before power-up to realize a finer set-point voltage in steady state or dynamically changed on a cycle by cycle basis during the operation for the purpose of a smoother start-up ramp generation or dynamic voltage scaling. A conceptual diagram in FIG. 3 illustrates this operation for the case where shift=2.

In this embodiment, the designs of DAC and ADC are independent so it offers design flexibility in choosing separate architectures.

The foregoing description of preferred embodiments of the present invention has been provided for the purposes of illustration and description. It is not intended to be exhaustive or to limit the invention to the precise forms disclosed. Many embodiments were chosen and described in order to best explain the principles of the invention and its practical application, thereby enabling others skilled in the art to understand the invention for various embodiments and with various modifications that are suited to the particular use contemplated. It is intended that the scope of the invention be defined by the claims and their equivalents.

1. A system comprising:
a Digital-to-Analog Converter (DAC) to produce an analog reference value from a first reference input, the analog reference value and an output value being used to produce an analog error signal;
an Analog-to-Digital Converter (ADC) to convert the analog error signal to a digital value, the ADC having a higher level of resolution than the DAC; and
an error encoder to receive the digital value and adjust the digital value to produce a digital error value using a second reference input.

2. The system of claim 1, wherein the output value is an output voltage.

3. The system of claim 1, wherein the output value is an output current.

4. The system of claim 1, wherein the ADC is a windowed ADC that operates over a narrower range than the DAC.

5. The system of claim 1, wherein the ADC encodes steps that are an integer n times smaller than the steps produced by the DAC.

6. The system of claim 1, wherein the second reference input is a shift value that is used to adjust the digital value to produce the digital error value.

7. The system of claim 1, wherein the digital error value is used to adjust the output value.

8. The system of claim 1, wherein the digital error value is used to adjust a digital pulse width modulator (DPWM).

9. The system of claim 1, wherein the digital error value is used for a DC-to-DC converter.

10. A method of producing a digital error signal comprising:
using a Digital-to-Analog Converter (DAC) to produce an analog reference value from a first reference input;
using the analog reference value and an output value to produce an analog error signal;
using an Analog-to-Digital Converter (ADC) to produce a digital output from the analog error signal;
adjusting the digital output with the second reference input to produce a digital error signal.

11. The method of claim 10, wherein the output value is an output voltage.

12. The method of claim 10, wherein the output value is an output current.

13. The method of claim 10, wherein the ADC is a windowed ADC that operates over a narrower range than the DAC.

14. The method of claim 10, wherein the ADC encodes steps that are an integer n times smaller than the steps produced by the DAC.

15. The method of claim 10, wherein the second digital reference input is a shift value that is used to adjust the digital value to produce the digital error value.

16. The method of claim 10, wherein the digital error value is used to adjust the output value.

17. The method of claim 10, wherein the digital error value is used to adjust a digital pulse width modulator (DPWM).

18. The method of claim 10, wherein the digital error value is used for a DC-to-DC converter.
